(19) United States
(12) Patent Application Publication
(10) Pub. No.: US 2026/0210588 A1
(43) Pub. Date: Jul. 23, 2026

(54) Thermoelectric Temperature Controller

(71) Applicant: Vymore BV, Ghent (BE)

(72) Inventor: Bram VAN DE MOORTEL, Ghent (BE)

(21) Appl. No.: 19/436,299

(22) Filed: Dec. 30, 2025

(30) Foreign Application Priority Data
Dec. 30, 2024 (BE) 2024/5962

(51) Int. Cl. F25B 21/02; C23C 16/52

(52) U.S. Cl. CPC F25B 21/02; C23C 16/52; F25B 2321/0212; F25B 2321/023

(57) ABSTRACT

The invention relates to an improved apparatus for temperature control of liquid chemicals in a sealable container, typically a bubbler container, inter alia for use in chemical vapor deposition (CVD).

### TECHNICAL FIELD

The field of the invention relates to a system for temperature regulation of liquid chemicals in a so-called bubbler container, in order to volatilize and discharge them for further use, for example in chemical vapor deposition (CVD).

### PRIOR ART

In the current prior art, temperature controllers for liquid chemicals are widely used in processes such as Chemical Vapor Deposition (CVD). These processes require precise temperature regulation to control the vapor pressure of the chemicals and to optimize the transfer of molecules to a process chamber.

An example of this includes U.S. Pat. No. 4,612,772A. This describes a thermoelectric temperature controller for a liquid chemical bubbler container in which a thermally conductive platform in the housing is heated or cooled by thermoelectric devices for heating or cooling a liquid chemical bubbler container to maintain a preset temperature. The housing is formed with a laterally opening door to provide an access opening that enables lateral installation and removal of the bubbler container into and out of the housing onto the thermally conductive platform. A heat exchanger is provided for the side walls of the bubbler container and comprises a first semi-cylindrical portion mounted at its lower end on the thermally conductive container support platform in heat exchange relation therewith and extending upwardly around the side walls of the bubbler container, and a second movable heat exchange portion that can be moved laterally through the access opening in the housing into opposing relation with the first heat exchange portion to form a heat exchange enclosure therewith. The adjacent sides of the first and second heat exchange elements are shaped to form interlocking cams that move the second heat exchange element laterally toward the first heat exchange element when the second heat exchange element moves downward into engagement with the thermally conductive container support platform.

However, the existing systems exhibit several shortcomings. First of all, the temperature sensitivity is often limited to 0.1° C., which can lead to delayed responses to temperature fluctuations, especially when the carrier gas begins to flow or the ambient temperature fluctuates. This can result in an inaccurate transfer of the liquid molecules, which can affect the quality of the produced microchips.

Moreover, some existing systems have a limited cooling capacity, which can lead to performance degradation as the system ages. This is particularly problematic in environments where the temperature can vary significantly.

Finally, the maintenance of these systems is often cumbersome, especially when it comes to replacing the liquid containers, which requires additional space and time. Each of these limitations emphasizes, certainly in combination, the need for improved temperature regulation systems that are both more accurate and more efficient, and that can be better integrated into contemporary production processes.

### SUMMARY OF THE INVENTION

The invention relates to an improved thermoelectric apparatus for temperature control of liquid chemicals in a sealable container, the container comprising a bottom wall, upstanding side walls, and a top wall, wherein the container is further provided with a temperature probe for measuring the temperature of the chemicals in the container, an inlet for receiving a carrier gas to below the level of the liquid chemicals, and an outlet for removing atmospheric gas from the container. The apparatus comprises a thermally conductive support platform, suitable for receiving the container thereon and cooling and/or heating the container and the chemicals therein, and a cooling plate configured for dissipating excess heat. This apparatus further comprises a thermoelectric element configured for controllably transferring heat between a first and a second side by means of passing a current through the thermoelectric element, wherein the thermoelectric element is thermally connected on the first side to the support platform, and on the second side thermally connected to the cooling plate. In addition, one or more connection points are provided that are suitable for coupling to the temperature probe of the container, and a control unit configured for driving the thermoelectric element by means of passing a current through the thermoelectric element, wherein the transferred heat is controlled over time by pulse width modulation of the current, wherein the pulse width modulation occurs at a frequency of at least 1000 Hz, preferably at least 1500 Hz. The current is provided by means of a current source. The control unit is connected to the one or more connection points and is configured for reading temperature data from a temperature probe coupled to the one or more connection points with a readout unit.

The apparatus comprises a housing, which comprises a housing base and a top piece, wherein the housing base comprises the support platform, the cooling plate, the current source, the readout unit, the control unit, the one or more connection points, and the thermoelectric element. The housing base and the top piece together form a cavity suitable for form-fittingly encompassing the container over substantially the entire height thereof. The top piece comprises internal side walls that partially define the side walls of the cavity, and wherein said internal side walls are in thermal contact with the support platform. The cooling plate is comprised in a base of the housing, wherein the support platform is provided on the base together with the side walls. The control unit and the current source are distanced from each other over a distance greater than 50%, preferably 75%, of the sides of the base. The thermoelectric element is integrated in a thermally insulating separator which separates the cooling platform and the support platform from each other.

Further embodiments are described in the dependent claims, as well as in the description that follows.

In a second aspect, the invention relates to the use of the apparatus for “bubbling” a precursor liquid in a “bubbler” container for evaporating or atomizing the precursor liquid, for use in, among others, chemical vapor deposition (CVD) applications.

### DESCRIPTION OF THE FIGURES

FIG. 1 shows a rear view of an embodiment of the apparatus.

FIG. 2 shows a perspective view of an embodiment of the rear side of the apparatus.

FIG. 3 shows the support platform, the cooling plate, and the separator according to an embodiment of the invention.

FIG. 4 shows a lateral cross-sectional view of the elements from FIG. 3.

FIGS. 5A and 5B show an embodiment of the apparatus, with and without the top piece.

### DETAILED DESCRIPTION

The term “thermoelectric apparatus” refers in the present invention to an apparatus designed for the precise temperature control of liquid chemicals within a sealed container. This apparatus uses thermoelectric elements to enable heating and cooling, and serves to atomize, evaporate, or volatilize the liquid chemicals for further use in a gaseous state, typically in CVD applications.

The term “container” refers in the present invention to a vessel comprising a bottom wall, side walls, and a top wall, which can be sealed and is provided with a temperature probe, an inlet for carrier gas below the liquid level, and an outlet for removing atmospheric gas.

The term “temperature probe” refers to a temperature sensor, such as a PT100 resistance temperature detector, which is used to measure the temperature of the chemicals within the container.

The term “thermally conductive support platform” refers to a thermally conductive support platform designed to receive the container and to facilitate heating or cooling. The term “cooling plate” refers to a cooling plate that is configured to efficiently dissipate excess heat.

The term “thermoelectric element” refers to an element, such as a Peltier element, that transfers heat between two sides when an electric current passes through it. It is thermally connected to the support platform on one side and the cooling plate on the other side.

The term “connection points” refers to connection points that are suitable for providing interfacing with the temperature probe of the container.

The term “control unit” refers to a control unit that is configured to regulate the thermoelectric element by modulating the current via pulse width modulation at a frequency of at least 1,000 Hz, preferably 1,500 Hz, to control the heat transfer over time.

The term “housing” refers to a housing that comprises a housing base and an upper section, which together form a cavity that accommodates the container over substantially its entire height.

The term “cavity” refers to the space formed by the housing base and the upper section, which is designed to closely fit and enclose the container.

The term “current source” refers to a power supply that delivers the required current for the operation of the apparatus, preferably operating on direct current. Preferably, it is powered from an external current source, and this energy is converted into a desired current.

The term “readout unit” refers to a readout unit that contains an analog-to-digital converter (ADC), which is capable of converting analog data from the temperature probe to a digital output with a precision of at least 0.01° C.

The term “current protection element” refers to a current protection element that measures the current through the thermoelectric element and activates alarm functions based on predefined threshold values.

The term “thermally insulating separator” refers to a thermally insulating separator that integrates the thermoelectric element and separates the cooling plate and the support platform from each other.

The term “ventilation openings” refers to ventilation openings in the housing for dissipating warm air from the cooling plate.

The term “digital display” refers to a digital display, optionally with a control panel, that is used for user interaction and monitoring of the functions of the apparatus.

In a first aspect of the invention, an apparatus is presented that significantly improves the operational efficiency and accuracy of temperature control in chemical processes. The apparatus distinguishes itself by its unique design, which comprises a thermally insulating separator or separation plate between the cooling platform and the support platform. This separation plate plays a crucial role in minimizing the accumulation of chemical residues on the thermoelectric elements. This design leads to significantly reduced maintenance requirements and extends the lifespan of the apparatus, resulting in lower operational costs and higher reliability for the user.

By providing a separator between the support platform, which is used for heating and cooling, and the cooling plate, which is used for dissipating heat, the system becomes more efficient, and unwanted heat is kept away from zones where it is not desired (depending on whether the support platform needs to cool or heat). Additionally, the thermoelectric element is also protected from external temperature fluctuations that can cause degradation.

The apparatus uses a high-frequency modulation of the current through the thermoelectric element, which enables a fast response to temperature fluctuations. This fast response is essential for precise temperature control, which directly contributes to improved production results. The ability of the apparatus to quickly detect and anticipate changes in the temperature profile of a chemical process makes it an indispensable instrument for efficient and reliable temperature regulation in various industrial applications.

More specifically, this high-frequency current modulation allows ensuring the reliability of the cooling characteristics of the system over a long period of time (10-20 years, typically even longer), without appreciable degradation. In existing systems, the cooling strength decreases rapidly after prolonged use, requiring these systems to either be replaced sooner, maintained more frequently, or alternatively resulting in unreliable cooling that is difficult to control and requires some time to provide a desired cooling level by means of a feedback mechanism, thus fluctuating around the desired temperature with periods in which the liquid becomes too warm and then too cold again, causing the resulting vapor pressure to not be constant, as required. It goes without saying that such cooling does not achieve the desired or required quality needed in these highly sensitive processes.

In certain prior art systems, controllable cooling is not even used; instead, a “brute force” approach is employed, in which the cooling has a fixed output, and the desired temperature is then achieved by controlling an additional heating element (silicone heater) to “correct” the cooling. It goes without saying that such a system is not only inefficient but will again operate via a feedback mechanism, thus introducing delays and producing periods in which too much and too little heat is provided. In addition, this approach can also lead to local temperature differences across the bubbler container, which is detrimental to the evaporation process.

Pulse width modulation or PWM allows controlling the power at which cooling is performed. In the prior art, this is typically carried out at a frequency between 100 and 300 Hz, which allows effectively providing a fairly constant heat flux, since the rapid switching produces a seemingly constant result. However, for the thermoelectric element, typically a Peltier element, this constant switching on and off of the current leads to rapid degeneration of the element. This is due, inter alia, to the rapid change in temperature in the element, which can lead to thermal stress in the element, from which material fatigue and other technical defects may follow. As a result, the cooling characteristics decrease over time. In the case of a “smart” system, this can potentially be compensated by continuously increasing the delivered power in order to still guarantee constant cooling, but this only causes faster degeneration and can also lead to complete failure of the element.

However, by modulating at a substantially higher frequency (a factor of 10 or even higher), the applicant succeeds in avoiding these problems. The high frequency ensures that the switching on and off becomes less “noticeable” to the thermoelectric element, because the extremes between the temperature for the element become less pronounced, and a leveling out of the temperature occurs, also very locally.

Preferably, the PWM frequency is set to more than 1 kHz, more preferably to more than 1.5 kHz, still more preferably to more than 2.0 kHz, and even more preferably to more than 2.5 kHz, such as 2,667 Hz or more, e.g. 3.0 kHz or 3.5 kHz. This choice ensures smoother operation and improved performance over longer periods of time. By maintaining peak performance, the temperature controller optionally supports high-precision applications, where even small deviations in temperature can have significant effects on the outcome.

In a preferred embodiment, the apparatus provides precise temperature control, wherein the temperature can be controlled to within 0.01° C. This high degree of accuracy is achieved through the application of a high-resolution analog-to-digital converter, which is capable of generating extremely accurate temperature data. This results in improved monitoring and control over the temperature process, which is particularly advantageous in critical applications such as semiconductor manufacturing. In this way, faster responses to fluctuations in the temperature of the liquid can be achieved, given that there is often a certain “inertia” involved. By responding earlier, an excessive deviation is avoided, and a constant vapor pressure is ensured.

The apparatus thus also offers improved process analyses and optimizations thanks to the accurate digital output. This is particularly useful in applications where the smallest temperature variations can have major consequences, such as in the manufacture of microchips. The ability to control the temperature to within 0.01° C. ensures a high degree of process control and consistency.

In a further preferred embodiment, the apparatus can be provided with external communication protocols and connection points, such as Ethernet, to promote seamless integration into existing process control systems. This makes it possible to operate and monitor the apparatus remotely, which contributes to the flexibility and efficiency of the production process. The apparatus is therefore eminently suitable for applications that require a high degree of precision and control, such as in the semiconductor industry and other advanced production systems.

In a preferred embodiment, the apparatus with the cavity defines a structure that provides improved heat transfer from the support platform, where heat is supplied or removed not only along the bottom side, via the support platform, but also along the side walls of the housing base and the top piece, leading to more efficient temperature regulation. This innovative construction of the apparatus additionally prevents thermal bridging between the (typically aluminum) housing and the container to be cooled by separating the external housing from the support platform and the walls connected thereto via an insulation layer, resulting in more effective cooling.

Preferably, low-resistance MOSFET switches are placed adjacent to the Peltier elements, whereby the apparatus optimizes energy transfer, resulting in improved cooling efficiency and reduced heat loss. Preference is given to a configuration in which the thermal insulation is maximized, so that heat transfer to the environment is minimized, which contributes to more efficient operation of the apparatus. The use of high-quality materials and components further contributes to the durability and reliability of the system, making it suitable for prolonged use in demanding industrial environments.

The construction can be further optimized through the use of advanced cooling technologies, such as the use of multiple Peltier elements that work together to maintain the desired temperature, as well as ensuring a better distribution of the heat flux to or from the support platform. These elements can preferably be controlled by an advanced control system that is capable of responding quickly to changes in the ambient temperature, thereby ensuring the stability of the process. In a more preferred embodiment, the control system can be programmed to support various operating modes, depending on the specific requirements of the application.

A preferred embodiment of the apparatus also offers the possibility of adapting the configuration to specific customer needs, whereby the apparatus can be flexibly deployed in various applications. This can include, inter alia, that the configuration of the cooling plates and the fan can be adapted to meet specific cooling requirements, or that the software can be updated to support new functions and capabilities. By virtue of this versatility, the apparatus is a valuable addition to any advanced manufacturing process in which precise temperature control is crucial.

In a preferred embodiment, the apparatus comprises a digital display that is provided on the apparatus itself, and is preferably placed at an ergonomic height, whereby the ease of use for the user is increased. This leads to more efficient operation and significantly reduces the likelihood of errors. The digital display provides a clear and direct representation of the current status and settings of the apparatus, which contributes to an intuitive user experience. Moreover, the optional control panel makes it possible to adjust the settings precisely, which further increases the flexibility in use. By virtue of the construction with a semi-open cavity, space is saved at the base of the apparatus where the display can be provided.

Furthermore, the apparatus preferably comprises low-ohmic MOSFET switches that operate with minimal energy loss. These switches maximize the energy transfer to the Peltier elements, which results in an improved overall cooling performance. The low resistance of the MOSFET switches contributes to an optimal electrical efficiency, which increases the overall energy efficiency of the system. These aspects ensure that the apparatus not only functions efficiently, but also remains reliable under various operational conditions. Preferably, the resistance of these switches is at most 25 milliohm, more preferably at most 10 milliohm, and even more preferably at most 10 milliohm. The combination of these features makes the apparatus a versatile and high-quality apparatus that is suitable for a wide range of applications in which accuracy and reliability are of crucial importance.

In a preferred embodiment, the apparatus comprises ventilation openings that are placed below the digital display. This design provides efficient heat dissipation, which contributes to improved thermal management of the apparatus. The ventilation openings are preferably designed in such a way that they optimize the airflow, whereby the heat generated by the internal components is effectively dissipated. This reduces the likelihood of overheating and extends the service life of the apparatus.

In a preferred embodiment, the apparatus comprises an adjustable fan at the cooling plate, which results in quieter operation when desired and contributes to a more comfortable and less disruptive working environment.

In a preferred embodiment, the apparatus has a compact front-loading functionality, which increases the flexibility of installation improvements and enables a simpler integration into various equipment configurations without imposing excessive spatial requirements, wherein the bubbler container must be placed into the cavity from above, which is often inconvenient and dangerous for the user, who has little grip on the container. This preferred version makes it possible to use the apparatus in environments with limited space, which increases the versatility of the apparatus.

In a further preferred embodiment, the apparatus provides a partial front-loading functionality, wherein the cavity in which the container is received is partially accessible via a horizontal movement, so that the container is already partially contained in the cavity, and can then subsequently be moved downward over a limited distance, which greatly simplifies the placement and removal of a container. Users can easily tilt and remove the liquid container without requiring extra space above the apparatus. This design is particularly advantageous in environments where space is limited, and makes it possible to quickly perform maintenance or replacements, which increases operational efficiency.

In a further preferred embodiment, ventilation openings at the rear of the apparatus can contribute to uniform heat dissipation. This design ensures that the internal components are less exposed to excessive heat, which benefits the reliability and performance of the apparatus in the long term. The apparatus can thereby continue to function optimally under various environmental conditions.

In a preferred embodiment, the internal side walls are encased by a layer of foam insulation, thereby reducing heat exchange with the environment.

Further preferably, a magnet alarm can be provided in the foam insulation, enabling rapid detection of misalignment. By quickly intervening in case of misalignment, the apparatus can ensure that temperature regulation remains consistent, which is crucial for processes that depend on precise temperature control.

The combination of these features in a preferred embodiment makes the apparatus particularly suitable for applications that require precise temperature regulation. The improved heat dissipation, simplified maintenance, and increased process integrity all contribute to the overall effectiveness and reliability of the apparatus in diverse industrial environments.

In a preferred embodiment, the apparatus may comprise a system for monitoring the current flowing through the thermoelectric element. This system preferably includes the ability to set alarm thresholds that can activate warnings when abnormal current levels are detected. Such a function enables the system to respond quickly to prevent potential overheating scenarios (or substandard performance), thereby ensuring the protection of the equipment. The ability to monitor the internal temperature is optionally included, enabling anticipatory adjustments that maintain stability, even amid external environmental fluctuations. This function is particularly advantageous in environments where external temperatures vary significantly, as it enables the apparatus to adapt its operation without compromising performance. Additionally, this is useful for actively counteracting unexpected temperature changes in the environment (e.g., air conditioning failure).

In a preferred embodiment, the apparatus comprises a second alarm function that shuts down the apparatus in the event of abnormal current deviations where an excessively high current is detected. This function provides increased safety and offers protection against overheating of the liquid. The alarm function is preferably configured such that it not only shuts down the apparatus, but also provides a warning to the user, so that immediate action can be taken. This contributes to safe operation of the apparatus, especially in environments where temperature control is crucial.

In a preferred embodiment, the apparatus comprises high-quality temperature connectors that increase the reliability of the apparatus by minimizing connector failure rates. These connectors are preferably designed to withstand mechanical wear and provide a stable connection throughout the lifespan of the apparatus. This ensures the accuracy and consistency of the temperature measurements.

In a further preferred embodiment, the apparatus can rapidly perform software updates in the field. This capability increases the adaptability of the apparatus to new technologies or user needs. By supporting rapid updates, the apparatus can easily be adapted to changing process requirements or improved functionalities, without the need for physical modification of the apparatus.

In a preferred embodiment, the apparatus uses a direct current source, which optionally improves the stability of the thermoelectric apparatus by minimizing vibrations and electrical noise. This design preferably minimizes electromagnetic interference, thereby preserving high-quality signals that optionally improve the precision and reliability of the system. The apparatus can preferably implement rapid and accurate temperature changes, thereby maintaining stable conditions, even during process fluctuations. The use of high-quality connectors in the apparatus further also provides guaranteed long-term reliability, thereby reducing maintenance needs and increasing performance consistency.

In a further preferred embodiment, the apparatus can achieve an improved level of thermal stability through the application of an advanced control system that maintains the temperature at a constant value, even in the presence of external disturbances such as fluctuations in ambient temperature or variations in airflow. The accuracy of the temperature control can optionally be further improved through the use of a precision temperature sensor that rapidly detects and corrects changes in temperature.

Furthermore, the apparatus can optionally make use of a range of high-quality materials and components that improve the durability of the apparatus and extend its lifespan. This preferably includes the use of robust housings and durable electronic components that are resistant to the challenges of industrial environments. The combination of these elements can optionally result in an apparatus that is not only accurate and reliable, but also durable and low-maintenance, thereby providing a cost-effective solution for temperature control in demanding applications.

In a preferred embodiment, the apparatus comprises a 4-20 mA input, which allows the apparatus to be connected to an external liquid level probe. This provides improved liquid level management, resulting in more accurate process control and less chance of accidental process failure. This feature is particularly valuable in environments where precision and continuity of the process are of crucial importance.

In a preferred embodiment, the apparatus is equipped with Ethernet communication, which significantly improves the integration of the apparatus into network architectures. This feature makes it possible to remotely operate and monitor the apparatus, which contributes to process automation and increased operational efficiency. Ethernet communication reduces the need for analog cables, which simplifies installation and increases flexibility in system design.

In that sense, a preferred embodiment of the apparatus comprises an Ethernet interface that simplifies integration into networks. This interface makes it possible to improve the control and communication of the apparatus, leading to more efficient apparatus management. More preferably, the Ethernet interface can be configured to be compatible with a wide range of network protocols, thereby increasing the flexibility and deployability of the apparatus in various industrial environments.

Furthermore, the apparatus temperature controller preferably supports various communication protocols, thereby increasing its versatility in various industrial applications. This adaptability is preferably achieved through the integration of Ethernet communication, which can reduce the need for multiple analog cables and thus streamline the installation process. The ability of the controller to operate at 24 VDC is preferably another property that distinguishes it from competitors, because the power supply can be located remotely from the unit, which may improve energy efficiency and reduce heat generation in enclosed spaces.

In a preferred embodiment, the apparatus provides for the measurement of the ambient temperature, which is used to adjust the operation of the thermoelectric element. This approach preferably ensures that a stable temperature is maintained in the chemical vapors above the wafers. By maintaining high precision and using advanced control mechanisms, the need for frequent maintenance is preferably reduced, which can lead to lower operational costs.

In a preferred embodiment, the temperature measurement sensitivity of 0.01° C. is achieved by making use of a Pt100 (resistance of 100 ohm at 0° C.) resistance-sensitive temperature probe, which can be calibrated to provide high accuracy over extended periods of time. This sensitivity ensures faster detection of temperature fluctuations, which can be quickly compensated by the cooling or heating functions of the controller. The use of a pulse width modulation technique at a frequency above 1 kHz to drive the Peltier elements is preferably another property that improves the cooling capacity and lifespan of the apparatus.

In a preferred embodiment, the apparatus can also comprise a partial front-loading design, which preferably enables easy installation of the liquid container with minimal overhead space. This compact design, together with the unique structure of the aluminum housing, which is manufactured in one piece, preferably ensures efficient cooling and minimizes the risk of liquid leakage, thereby improving operator safety. Overall, the combination of precision, reliability, and versatility of the apparatus temperature controller preferably positions it as a superior choice in temperature control applications.

In a preferred embodiment, the invention comprises improved heat transfer ensuring accurate temperature control through effective thermal conduction by the internal side walls of the housing base and the top piece. The apparatus is preferably equipped with a high resolution of 0.01° C., which provides maximum improvement in the precision of temperature control. This is particularly advantageous for applications where accurate temperature monitoring is essential, such as in processes that require consistent conditions to arise. The ability of the apparatus to detect small temperature changes contributes to the overall precision of the temperature control, which is crucial for the reliability and efficiency of the process.

In a further preferred embodiment, the apparatus can be provided with an advanced feedback mechanism that further refines the temperature control by making real-time adjustments based on the measured temperature changes. This can preferably be extended by means of an incremental algorithm to optimize the temperature control mechanism and improve the responsiveness of the system.

In a preferred embodiment, the temperature controller comprises side walls that are manufactured in one piece with the housing base, which ensures improved structural integrity and durability of the apparatus. This design optionally enables a more robust frame, thereby minimizing the risk of deformation or damage during operation. Preferably, this structure facilitates the efficient installation of the temperature controller in environments with limited overhead space, thereby enabling its integration into compact production setups. More preferably, the unique design of the apparatus ensures easy access and maintenance, which ensures minimal downtime and increased productivity.

The design of the insulation plate or separator is preferably configured to ensure the thermal insulation of the thermoelectric elements and the cooling plate. This ensures improved energy efficiency of the temperature controller and increased reliability. By reducing the thermal conductivity between the support platform (and the side walls of the cavity) and the cooling plate, the separator protects, inter alia, sensitive components against excessive exposure to heat, thereby extending their operational lifespan. More preferably, the thermal insulation contributes to maintaining consistent temperature control, which is crucial for processes that require high precision and reliability.

In a preferred embodiment, the apparatus comprises a cylindrical cavity design that contributes to improved heat efficiency. In this regard, all side walls of the cavity are thermally connected to the support platform, along which the heat transfer takes place. This design ensures a uniform distribution of heat over the liquid container, resulting in energy savings and stable temperature control. Optionally, the cylindrical cavity can be configured such that the heat transfer is further optimized, wherein the internal structure of the cavity is designed to maximize the thermal conductivity of the materials used.

In a preferred embodiment, the apparatus has an open upper side of the cavity, which contributes to a more compact installation. This preferably ensures that less vertical space is required, whereby the apparatus can easily be integrated into limited or existing spaces. This design choice makes it possible to use the apparatus in a wide range of applications in which space saving is a crucial factor.

The open upper side is then closed once the bubbler container has been placed, by means of a top piece that may already form part of the bubbler container, and which is provided with connections for the supply of a carrier gas and for the discharge of the produced vapors.

In a preferred embodiment, the apparatus comprises an advanced PID control system. This system preferably makes it possible to manage temperature changes quickly and accurately. The PID control system is designed to respond efficiently to changes in ambient temperature or other disturbances, allowing the desired temperature to be restored quickly. This precise control over temperature management is of great importance in applications where even small temperature deviations can affect the quality of the end product.

The combination of a compact design, improved electrical efficiency, reliable temperature connections, and an advanced control system preferably makes the apparatus a versatile and reliable choice for a wide range of industrial applications. These features preferably contribute to improved process stability and product quality, which ultimately leads to higher operational efficiency and lower costs.

In a preferred embodiment, the invention relates to an apparatus wherein the connection points, control unit, and current source are separated from each other by a distance of at least 10 cm. This separation optionally minimizes electromagnetic interference and prevents excessive heat accumulation within the housing. By physically separating these components, heat transfer between them is reduced, which optionally leads to less thermal stress and a longer lifespan of sensitive electronic components.

Preferably, the control unit is positioned such that it is at a distance of at least 10 cm from the current source, thereby further reducing electromagnetic interference. This results in more reliable communication and more accurate regulation of the temperature. The physical separation of the connection points optionally provides easy access to the connectors, which facilitates maintenance and minimizes the chance of connection problems.

More preferably, the invention relates to a structure wherein the distance between the components may vary, but ideally lies within a range of 10 cm to 20 cm. This range may be further extended to a distance of 5 cm to 25 cm, further still to 3 cm to 30 cm, and even to 2 cm to 35 cm, depending on the specific application and the available space within the housing.

In a more preferred embodiment, the apparatus may optionally make use of components that are specifically designed to reduce electromagnetic interference, such as shielded cables or housings with electromagnetic shielding. These measures contribute to the overall reliability and accuracy of the system.

In another preferred embodiment, the separation of the components may also contribute to more efficient heat dissipation, enabling the apparatus to operate in a broader temperature range. This temperature range may preferably lie between −10° C. and 60° C., more preferably between −5° C. and 55° C., even more preferably between 0° C. and 50° C., and most preferably between 5° C. and 45° C. These improvements in heat management and electromagnetic interference make the apparatus particularly suitable for use in demanding environments where precise temperature regulation is of crucial importance.

In a preferred embodiment, the frequency of the high-frequency modulation may preferably vary from 1 kHz to 5 kHz, more preferably from 1.5 kHz to 4.5 kHz, even more preferably from 2 kHz to 4 kHz, still more preferably from 2.5 kHz to 3.5 kHz, and most preferably around 2.667 kHz. This frequency optimization contributes to extending the lifespan of the Peltier elements and ensures that cooling efficiency is maintained, even after prolonged use.

Overall, the combination of these preferred features in the apparatus temperature controller provides a comprehensive solution for maintaining precise temperature control in various industrial applications. The improved durability, energy efficiency, and lifespan of the components collectively contribute to a reliable and effective temperature management system. These features are particularly advantageous in semiconductor manufacturing and other high-tech industries where precision and reliability are of the utmost importance.

### EXAMPLES

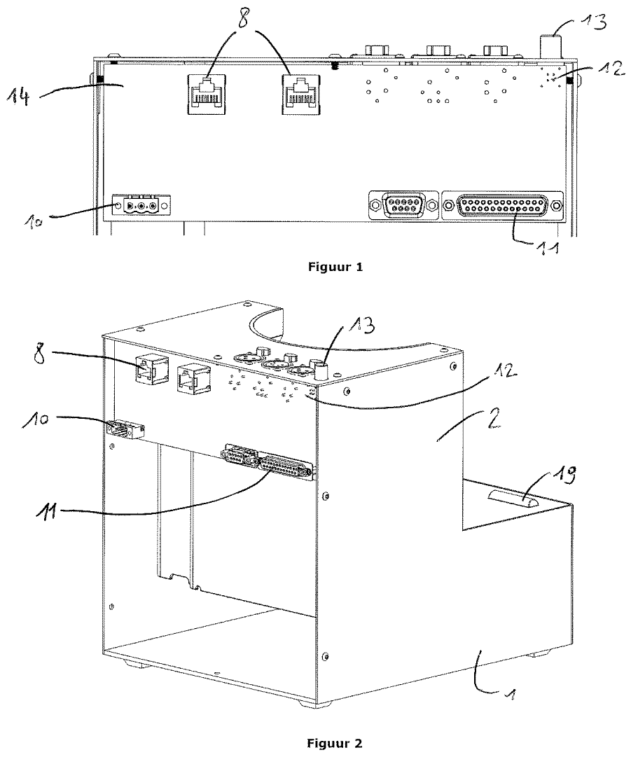

FIG. 1 shows a rear view of the apparatus (with a rear wall removed), wherein a number of the most important electronic components are visible. At the bottom right is a communication circuit (11) suitable for being connected to external systems. At the top right is, on one hand, a connection point (13) to which a temperature probe can be coupled, with below it, in the housing base (2), a readout unit (12) for reading out temperature data from the temperature probe.

At the bottom left is a connection (10) for external power supply, with above it a current source (14) that converts the external power supply into an appropriate current and voltage, for, inter alia, the thermoelectric element (7). Finally, at the top there are also two Ethernet connections (8).

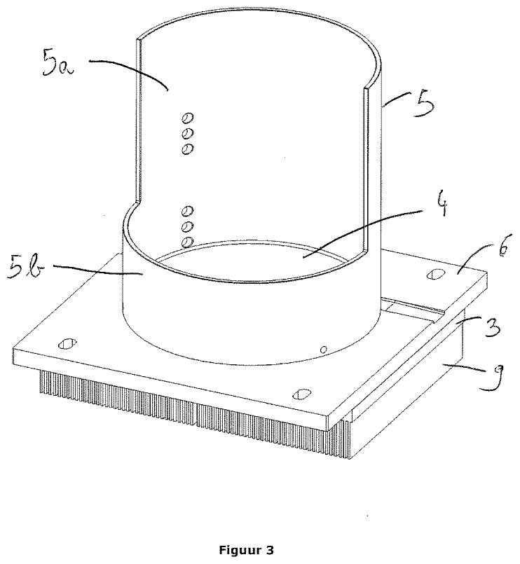

FIG. 2 shows a perspective view of the rear side of the apparatus (with a rear wall removed), wherein the housing base (1, 2) is visible. This comprises a base (1) and an upstanding section (2) that stands on the base and is located at the rear side of the apparatus. Together with the top piece (15), the base (1) and the upstanding section (2) define the cavity in which the liquid container (bubbler) can be provided. In FIG. 2, the connection point (13) for the temperature probe and the readout unit (12) are again visible, as are the connection (10) for external power supply, the current source (14), the two Ethernet connections (8), and the communication circuit (11).

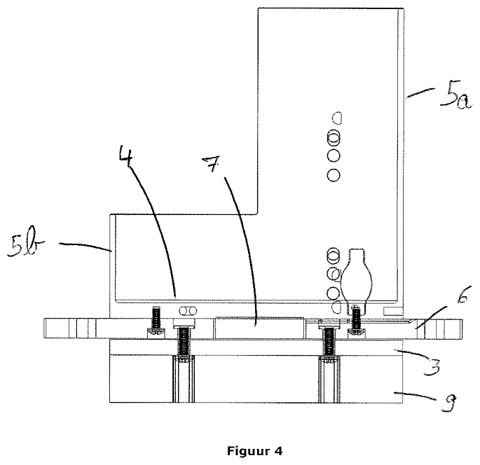

FIG. 3 shows the internal side walls (5) of the upstanding section (2) of the housing base, and the support platform (4) with which the internal side walls are thermally connected. The internal side walls at the rear side (5a) extend over the full height of the cavity to be formed, and the internal side walls at the front side (5b) only over a portion of the height. A top piece is subsequently fitted that “supplements” the shorter front side walls (5b) to the full length, and in doing so also makes a thermal connection with the internal side walls of the top piece and those of the upstanding section (5).

The support platform (4) is fixedly mounted on a thermally insulating separator (6), in which one or more (in this figure invisible) thermoelectric elements (7) are provided. At the underside of the separator (6), it is fixedly mounted on a cooling plate (3) with cooling fins (9).

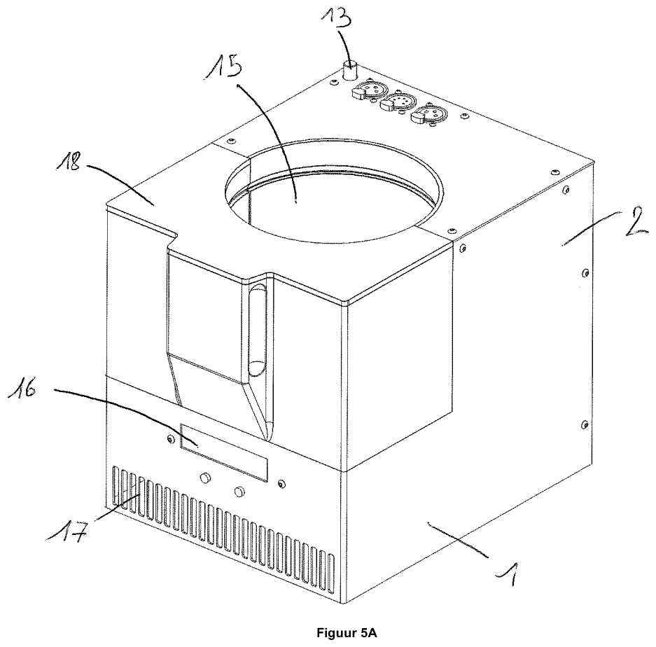

FIG. 4 shows a lateral cross-sectional view of the elements from FIG. 3. There it can be seen how a thermoelectric element (7) is built into the separator (6) and makes thermal contact with both the support platform (4) and the cooling plate (3), and in that way can create a heat flux in both directions, depending on how the thermoelectric element is driven. Both the support platform (4) and the cooling plate (3) are fixedly mounted on the separator (6), with a number of bolts, wherein however no thermal bridge is formed between the support platform and the cooling plate, except for the thermoelectric element, which is controllable, and the separator, which de facto does not function as a thermal bridge.

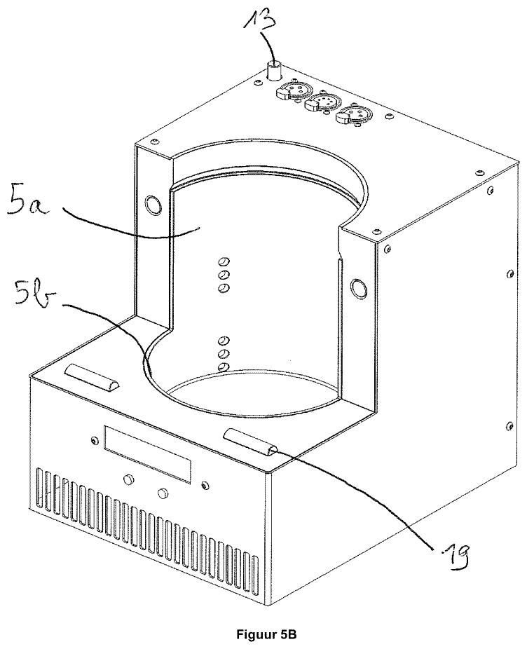

FIG. 5A shows an apparatus according to the invention, wherein the top piece (18) is placed on the housing base (1, 2), thereby defining the cavity (15). At the lower front, a digital display (16) with control buttons is also provided, which allows a user to perform operations directly on the apparatuses, such as adjustment of a temperature setpoint.

Below the display, a grille with ventilation openings (17) is visible, which allows an airflow to flow past the cooling plate (3) and cooling fins (9). This airflow is generated by an internal fan in the housing base.

FIG. 5B shows the housing base (1, 2) without the top piece (18), wherein the internal side walls (5a, 5b) of the upstanding section (2) are visible. On the base, alignment elements (19) are further provided over which a correspondingly shaped recess in the top piece (18) fits, to ensure that the cavity is optimally formed, and the internal side walls (5a, 5b) connect to those of the top piece (18) for heat transfer.

1. A thermoelectric apparatus for temperature control of liquid chemicals in a sealable container, the container comprising a bottom wall, upstanding side walls, and a top wall, wherein the container is further provided with a temperature probe for measuring the temperature of the chemicals in the container, an inlet for receiving a carrier gas to below the level of the liquid chemicals, and an outlet for removing atmospheric gas from the container, the apparatus comprising:
a. a thermally conductive support platform, suitable for receiving the container thereon and cooling and/or heating the container and the chemicals therein;
b. a cooling plate configured for dissipating excess heat;
c. a thermoelectric element configured for controllably transferring heat between a first and a second side of the thermoelectric element by means of passing a current through the thermoelectric element, wherein the thermoelectric element is thermally connected on the first side to the support platform, and on the second side thermally connected to the cooling plate;
d. one or more connection points suitable for coupling to the temperature probe of the container;
e. a control unit configured for driving the thermoelectric element by means of passing a current through the thermoelectric element, wherein the transferred heat is controlled over time by pulse width modulation of the current, wherein the pulse width modulation takes place at a frequency of at least 1,000 Hz, wherein the current is provided by means of a current source, and wherein the control unit is connected to the one or more connection points and is configured for reading out, by means of a readout unit, temperature data from a temperature probe coupled to the one or more connection points;
f. a housing comprising a housing base and a top piece, wherein the housing base comprises the support platform, the cooling plate, the current source, the readout unit, the control unit, the one or more connection points, and the thermoelectric element, and wherein the housing base and the top piece together form a cavity suitable for form-fittingly enclosing the container over substantially its full height, wherein the top piece comprises internal side walls that partially define side walls of the cavity, and wherein said internal side walls are in thermal contact with the support platform, wherein the cooling plate is comprised in a base of the housing, wherein the support platform is provided on the base together with the side walls;
wherein the control unit and the current source are distanced from each other over a distance greater than 50%, of the sides of the base, wherein the thermoelectric element is integrated in a thermally insulating separator which separates the cooling platform and the support platform from each other.

2. The thermoelectric apparatus according to claim 1, wherein the readout unit comprises an analog-to-digital converter (ADC) suitable for processing analog measurement data from the temperature probe into a digital output of at least 8 bit, wherein the digital output is accurate to 0.01° C.

3. The thermoelectric apparatus according to claim 1, wherein the cavity is defined at the underside by the housing base over the full circumference, and over at least 10%, of the height of the cavity.

4. The thermoelectric apparatus according to claim 3, comprising a digital display and control panel on the housing base at a height between the base and the top piece.

5. The thermoelectric apparatus according to claim 4, wherein the housing base has, at the front side, and optionally at the rear side, of the apparatus ventilation openings for dissipating warm air from the cooling plate, and wherein the ventilation openings at the front side are located below the digital display.

6. The thermoelectric apparatus according to claim 1, comprising a current protection element configured for measuring the current through the thermoelectric element, wherein a first alarm function is activated when a measured current is below a first predetermined threshold value, and a second alarm function is activated when a measured current is above a second predetermined threshold value.

7. The thermoelectric apparatus according to claim 6, wherein in the second alarm function the apparatus is switched off.

8. The thermoelectric apparatus according to claim 1, wherein the current source operates on direct current.

9. The thermoelectric apparatus according to claim 1, wherein the apparatus comprises a temperature sensor for measuring the ambient temperature, wherein the control unit is configured for controlling the thermoelectric element based on the measured ambient temperature.

10. The thermoelectric apparatus according to claim 1, wherein upstanding internal side walls of the housing base and the top piece together form the cavity, wherein said internal side walls are thermally conductive.

11. The thermoelectric apparatus according to claim 10, wherein the internal side walls of the housing base are integral with the support platform.

12. The thermoelectric apparatus according to claim 1, wherein the cavity is cylindrical and wherein the housing base and the top piece comprise a semi-cylindrical recess which face each other, wherein the housing base and the top piece together form the cavity, wherein the cavity is partially fully enclosed in the housing base above the support platform.

13. The thermoelectric apparatus according to claim 1, wherein the cavity has an open top side.

14. The thermoelectric apparatus according to claim 1, wherein the connection points and the control unit are provided on a first side, and the current source is provided on a second side of the housing.

15. The thermoelectric apparatus according to claim 1, wherein the support platform is anchored on the thermally insulating separator at the top side, and wherein the cooling plate is anchored on the thermally insulating separator at the bottom side, and wherein the one or more thermoelectric elements constitute the only thermal bridge between the support platform and the cooling plate.
